(19) United States
(12) Patent Application Publication
(10) Pub. No.: US 2016/0306243 A1
(43) Pub. Date: Oct. 20, 2016

(54) ACTIVE MATRIX ARRAY SUBSTRATE AND DISPLAY APPARATUS USING THE SAME

(71) Applicant: Century Technology (Shenzhen) Corporation Limited, Shenzhen (CN)

(72) Inventors: WEN-QIANG YU, Shenzhen (CN); JIAN-XIN LIU, Shenzhen (CN); MING-TSUNG WANG, New Taipei (TW); CHIH-CHUNG LIU, New Taipei (TW)

(21) Appl. No.: 14/790,573

(22) Filed: Jul. 2, 2015

(30) Foreign Application Priority Data
Apr. 15, 2015 (CN) 201510177356.7

(51) Int. Cl. G02F 1/1362; H01L 27/12

(52) U.S. Cl. CPC G02F 1/136286; G02F 1/136227; H01L 27/124; G02F 2001/136254

(57) ABSTRACT

An active matrix array substrate includes a base having an edge region along an edge of the base, a plurality of first wires arranged along a first direction on the base, a plurality of second wires arranged along a second direction perpendicular to the first direction on the base, and a detecting structure located in the edge region. The detecting structure detects the first wire and the second wire. The first wire and the second wire are extended into the edge region and are connected to the detecting structure. The detecting structure further includes a plurality of detecting pins, a plurality of detecting wires, and a plurality of conductive portions. The first wires and the second wires connect to the corresponding detecting pin via the conductive portion respectively. The conductive portion simultaneously covers at least two detecting pins. The detecting wires provides signals to an active matrix array substrate.

### CROSS-REFERENCE TO RELATED APPLICATIONS

This application claims priority to Chinese Patent Application No. 201510177356.7 filed on Apr. 15, 2015, the contents of which are incorporated by reference herein.

### FIELD

The subject matter herein generally relates to display apparatus with an active matrix array substrate.

### BACKGROUND

Active matrix display apparatus, such as a liquid crystal display (LCD) and an organic light-emitting display (OLED) includes an active matrix array substrate and an opposite substrate. The active matrix array substrate with a plurality of detecting wires and the opposite substrate are separately fabricated. An external detecting structure for detecting the active matrix array substrate includes a plurality of detecting pins and a conductive portion, and is provided to establish an electrical connection between the detecting wire and the detecting pin via the conductive portion.

### BRIEF DESCRIPTION OF THE FIGURES

Implementations of the present technology will now be described, by way of example only, with reference to the attached figures.

FIG. 1 is an isometric view of an embodiment of a display apparatus, the display apparatus comprising an active matrix array substrate.

FIG. 2 is a plan view of an embodiment of the active matrix array substrate of FIG. 1.

FIG. 3 is an enlarged diagrammatic view of circle III of an embodiment of the active matrix array substrate of FIG. 2.

FIG. 4 is an enlarged isometric of circle IV of an embodiment of the active matrix array substrate of FIG. 2.

FIG. 5 is a cross-sectional view taken along a line V-V of an embodiment of FIG. 4.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. The drawings are not necessarily to scale and the proportions of certain parts may be exaggerated to better illustrate details and features. The description is not to be considered as limiting the scope of the embodiments described herein.

The term “substantially” is defined to be essentially conforming to the particular dimension, shape or other word that substantially modifies, such that the component need not be exact. For example, substantially cylindrical means that the object resembles a cylinder, but can have one or more deviations from a true cylinder. The term “comprising” means “including, but not necessarily limited to”; it specifically indicates open-ended inclusion or membership in a so-described combination, group, series and the like.

The present disclosure is described in relation to a display apparatus 10 for improving detecting process.

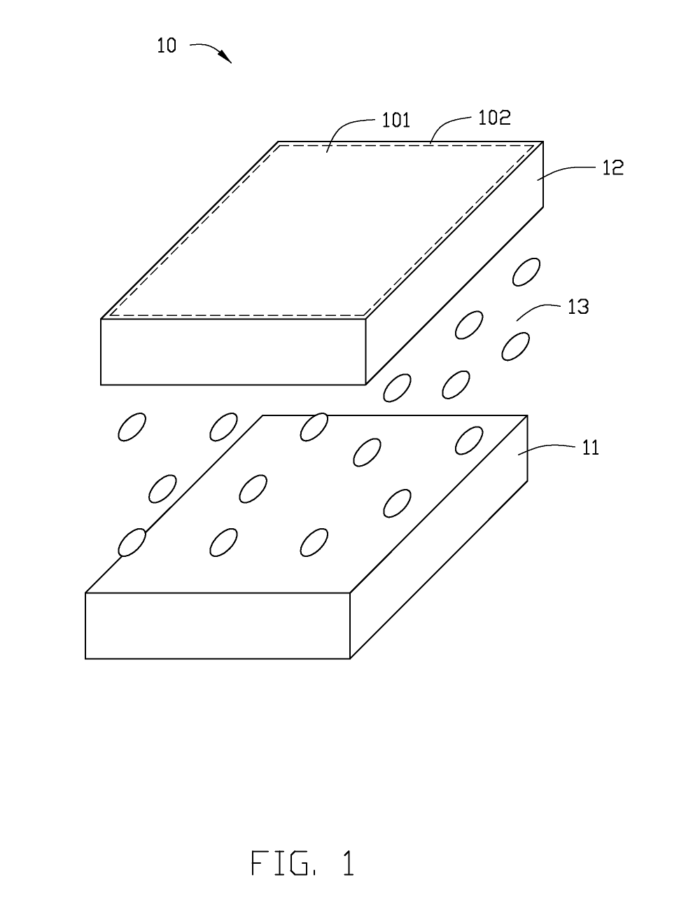

FIG. 1 illustrates a display apparatus 10 of the embodiment. The display apparatus 10 includes an active matrix array substrate 11, an opposite substrate 12 opposite to the active matrix array substrate 11, and a liquid crystal layer 13 sandwiched between the active matrix array substrate 11 and the opposite substrate 12. The display apparatus 10 further includes a display region 101 and a non-display region 102 surrounding the display region 101. The display region 101 is substantially rectangular shaped, and is set in a middle of the display apparatus 10. The non-display region 102 is substantially hollow rectangular frame.

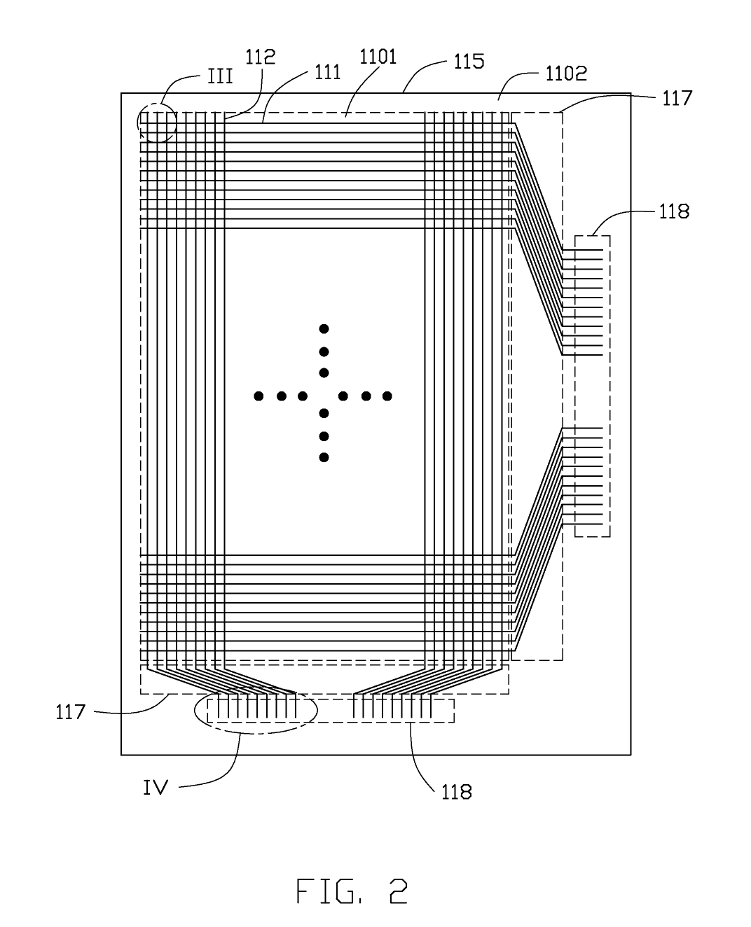

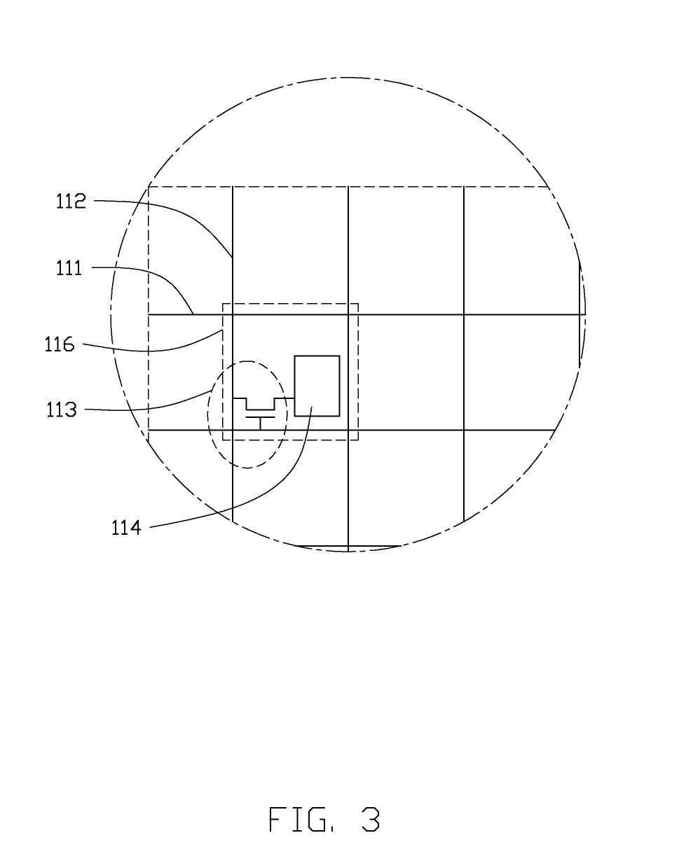

FIGS. 2-3 illustrate the active matrix array substrate 11 of the embodiment. The active matrix array substrate 11 includes a plurality of first wires 111 parallel with each other, a plurality of second wires 112 parallel with each other, a plurality of active components 113, a plurality of pixel electrodes 114, and a base 115. The first wire 111 is orthogonal to the second wire 112 to define a pixel region 116. The first wires 111 are extended along a first direction. The first wire 111 is used for providing a first signal to the active component 113. The second wires 112 are extended along a second direction. The second wire 112 is used for providing a second signal to the active component 113. The active component 113 is located on an intersection of the first wire 111 and the second wire 112 in the pixel region 116. The active component 113 is simultaneously electrically connected to the first wire 111 and the second wire 112, which cooperate with each other defining the pixel region 116. The pixel electrode 114 is located in the pixel region 116, and is electrically connected to the active component 113 in the same pixel region 116. In at least embodiment, the pixel electrode 114 is made of transparent electrical material, such as indium tin oxid (ITO) or indium zinc oxide (IZO). The base 115 is made of a transparent material, such as glass or quartz, or made of a non-transparent rigid inorganic, such as chip or ceramics, or is made of a flexible organics, such as plastic, rubber, polyester, or polycarbonate. The active component 113 is thin film transistor (TFT). The first wire 111 is a scan line, and the second wire 112 is a data line. In other embodiments, the first wire 111 is a data line, and the second wire 112 is a scan line.

The active matrix array substrate 11 further includes a function region 1101 corresponding to the display region 101, and an edge region 1102 corresponding to the non-display region 102. The function region 1101 is located in a middle of the active matrix array substrate 11. The function region 1101 is substantially rectangular shaped. The function region 1101 transmits light to form images on the display region 101 when powered. The edge region 1102 surrounds the function region 1101, and is a layout region for designing wires. The edge region 1102 includes at least one fan-out layout region 117 and at least one driving circuit region 118. The fan-out layout region 117 is located between the driving circuit region 118 and the function region 1101. The fan-out layer region 117, the driving circuit region 118, and the function region 1101 are spaced from each other. The first wire 111 passes through the function region 1101 along the first direction, and extends into the edge region 1102. The second wire 112 passes through the function region 1101 along the second direction and the fan-out layout region 117, and extends into the driving circuit region 118. In at least one embodiment, there are two fan-out layout regions 117 and two driving circuit regions 118. The fan-out layout regions 117 are respectively located on two adjacent edges of the active matrix array substrate 11, such as a bottom edge and a side edge. The driving circuit regions 118 are respectively located on two adjacent edges of the active matrix array substrate 11, and respectively correspond to the fan-out layout regions 117. In other embodiments, the active matrix array substrate 11 can include more than two fan-out layout regions 117 and more than two driving circuit regions 118.

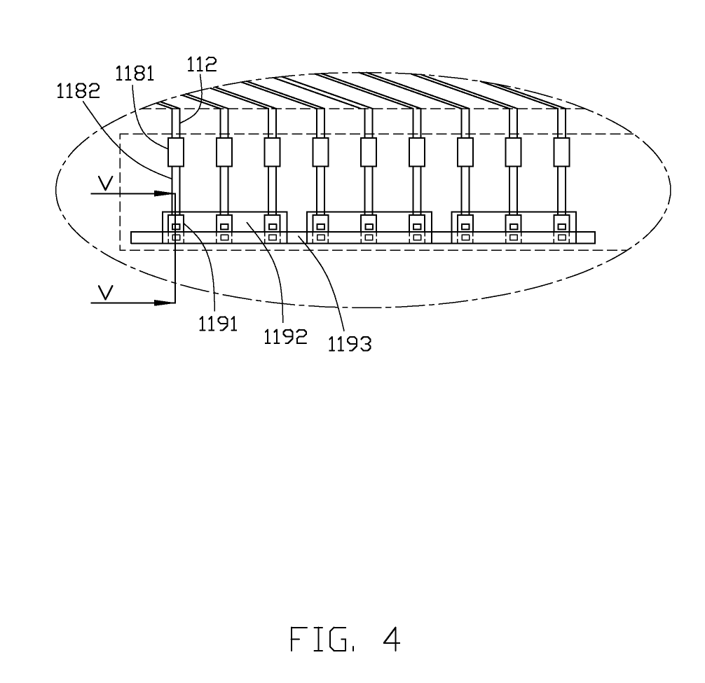

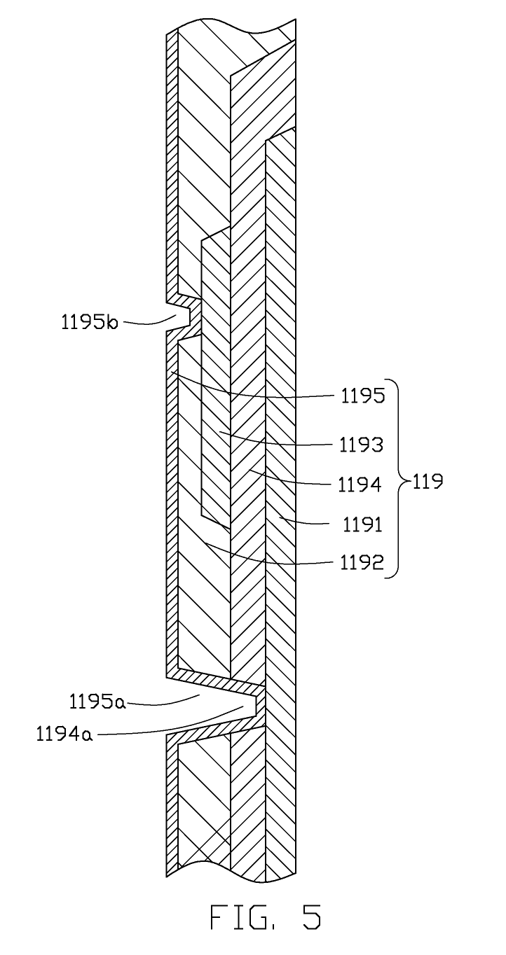

FIGS. 4 and 5 illustrate the driving circuit region 118 of the embodiment.

The driving circuit region 118 includes a detecting structure 119. The detecting structure 119 is located in the driving circuit region 118 of the edge region 1102. The driving circuit region 118 further includes a plurality of driving pins 1181 and a plurality of connecting wires 1182. The detecting structure 119 includes a plurality of detecting pins 1191, a plurality of conductive portions 1192, and a plurality of detecting wires 1193. Each of the driving pins 1181 is electrically connected to a driving chip, such as a source driver or a gate driver. An end of the driving pin 1181 is electrically connected to the first wire 111 or the second wire 112, an opposite end of the driving pin 1181 is electrically connected to the corresponding detecting pin 1191 via the corresponding connecting wire 1182. Each of the detecting wires 1193 is insulated from the detecting pin 1191, and is electrically connected to the corresponding detecting pin 1191 via the conductive portion 1192. The detecting wire 1193 is used for providing detecting signals to the active matrix array substrate 11.

The detecting structure 119 further includes a first insulating layer 1194 and a second insulating layer 1195. The detecting pins 1191 are located on the base 115, and the first insulating layer 1194 covers the detecting pins 1191 and the base 115. The detecting wire 1193 is located on the first insulating layer 1194, and is set on the upper of the corresponding detecting pin 1191. The first detecting wire 1193 is insulated from the detecting pin 1191 via the first insulating layer 1194. The second insulating layer 1195 is located on the detecting wires 1193, and covers the detecting wires 1193 and the first insulating layer 1194. The detecting wire 1193 is insulated from the conductive portion 1192 via the second insulating layer 1195. The first insulating layer 1194 defines at least one through hole 1194a. The first through hole 1194a corresponds to the detecting pin 1191. The second insulating layer 1195 includes at least one second through hole 1195a and at least one third through hole 1195b. The second through hole 1195a located on the first through hole 1194a communicates with the first through hole 1194a. The second through hole 1195a cooperates with the first through hole 1194a allowing the detecting pin 1191 to be exposed. The third through hole 1195b corresponding with the detecting wire 1193 is configured to expose the detecting wire 1193. The detecting pin 1191 and the detecting wire 1193 are connected via the conductive portion 1192 passed through the first through hole 1194a, the second through hole 1195a, and the third through hole 1195b. In at least one embodiment, a number of the first through holes 1194a is equal to a number of the second through holes 1195a. The conductive portion 1192 is made of transparent electrical material, such as indium tin oxid (ITO) or indium zinc oxide (IZO). In other embodiments, the conductive portion 1192 is made of other conductive material, such as conductive metal.

From a top view, each of the conductive portions 1192 simultaneously covers at least two of the detecting pins 1191. In at least one embodiment, the conductive portion 1192 simultaneously covers three detecting pin 1191. A length of the conductive portion 1192 is in a range from 92.4 micron (μm) to 154 μm.

When the active matrix array substrate 11 satisfies a request, the connecting wire 1182 is cut off via a laser or other manners, which cause the driving pin 1181 to be insulated from the corresponding detecting pin 1191. Then, driving ICs are mounted on the driving circuit region 118, and the active matrix array substrate 11 and the opposite substrate 12 are assembled and filled with crystals to form the display apparatus 10.

In use, the conductive portions are separately arranged, and each of the conductive portions covers at least two detecting pins. Therefore, the detecting process of the active matrix array substrate is improved.

While various exemplary and preferred embodiments have been described, the disclosure is not limited thereto. On the contrary, various modifications and similar arrangements (as would be apparent to those skilled in the art) are intended to also be covered. Therefore, the scope of the appended claims should be accorded the broadest interpretation so as to encompass all such modifications and similar arrangements.

What is claimed is:

1. An active matrix array substrate comprising:
a base having an edge region along an edge of the base;
a plurality of first wires arranged along a first direction on the base;
a plurality of second wires arranged along a second direction perpendicular to the first direction on the base;
an edge region; and
a detecting structure located in the edge region, and configured to detect the first wire and the second wire;
wherein the first wire and the second wire are extended into the edge region and are connected to the detecting structure; the detecting structure further comprises a plurality of detecting pins, a plurality of detecting wires, and a plurality of conductive portions; the first wires and the second wires connect to the corresponding detecting pin via the conductive portion respectively; the conductive portion simultaneously covers at least two detecting pins, the detecting wires are each connected with a corresponding detecting pin via the conductive portion, the detecting wires for providing signals to an active matrix array substrate.

2. The active matrix array substrate of claim 1, wherein the detecting structure further comprises a first insulating layer and a second insulating layer; the first insulating layer covers on the detecting pins, and the detecting wires are located on the first insulating layer; the second insulating layer covers on the detecting wires.

3. The active matrix array substrate of claim 2, wherein the first insulating layer defines a plurality of first through holes; the first through hole corresponds to the detecting pin.

4. The active matrix array substrate of claim 2, wherein the second insulating layer defines a plurality of second through holes and a plurality of third through holes; the second through hole communicates to the first through hole; the second through hole cooperates with the first through hole to expose the detecting pin.

5. The active matrix array substrate of claim 4, wherein the second insulating layer further defines a plurality of third through holes; the third through hole corresponding to the detecting wire is used for exposing the detecting wire.

6. The active matrix array substrate of claim 1, wherein each of the conductive portions simultaneously covers three detecting pins.

7. The active matrix array substrate of claim 1, wherein a length of the conductive portion is in a range from 92.4 μm to 154 μm.

8. A display apparatus comprising:
an opposite substrate;
a liquid crystal layer; and
an active matrix array substrate configured to cooperate with the opposite substrate for sandwiching the liquid crystal layer, and the active matrix array substrate comprising:
a base;
a plurality of first wires arranged along a first direction on the base;
a plurality of second wires arranged along a second direction perpendicular to the first direction on the base;
an edge region; and
a detecting structure located in the edge region, and configured to detect the first wire and the second wire;
wherein the first wire and the second wire are extended into the edge region and are connected to the detecting structure; the detecting structure further comprises a plurality of detecting pins, a plurality of detecting wires, and a plurality of conductive portions; the first wires and the second wires connect to the corresponding detecting pin via the conductive portion respectively; the conductive portion simultaneously covers at least two detecting pins.

9. The display apparatus of claim 8, wherein the detecting structure further comprises a first insulating layer and a second insulating layer; the first insulating layer covers on the detecting pins, and the detecting wire is located on the first insulating layer; the second insulating layer covers on the detecting wires.

10. The display apparatus of claim 9, wherein the first insulating layer defines a plurality of first through holes; the first through hole corresponds to the detecting pin.

11. The display apparatus of claim 10, wherein the second insulating layer defines a plurality of second through holes and a plurality of third through holes; the second through hole communicates to the first through hole; the second through hole cooperates with the first through hole to expose the detecting pin.

12. The display apparatus of claim 11, wherein the second insulating layer further defines a plurality of third through holes; the third through hole corresponding to the detecting wire is used for exposing the detecting wire.

13. The display apparatus of claim 8, wherein each of the conductive portion simultaneously covers three detecting pins.

14. The display apparatus of claim 13, wherein a length of the conductive portion is in a range from 92.4 μm to 154 μm.
